(19) United States
(12) Patent Application Publication
(10) Pub. No.: US 2014/0054531 A1
(43) Pub. Date: Feb. 27, 2014

(54) DEFECT ENHANCEMENT OF A SWITCHING LAYER IN A NONVOLATILE RESISTIVE MEMORY ELEMENT

(71) Applicants: Nan Lu, San Jose, CA (US); Imran Hashim, Saratoga, CA (US); Jinhong Tong, Santa Clara, CA (US); Ruey-Ven Wang, Santa Clara, CA (US)

(72) Inventors: Nan Lu, San Jose, CA (US); Imran Hashim, Saratoga, CA (US); Ronald Kuse, San Diego, CA (US); Jinhong Tong, Santa Clara, CA (US); Ruey-Ven Wang, Santa Clara, CA (US)

(73) Assignee: Intermolecular, Inc., San Jose, CA (US)

(21) Appl. No.: 13/594,395

(22) Filed: Aug. 24, 2012

(51) Int. Cl. H01L 47/00; H01L 21/02

(52) U.S. Cl. 257/2; 438/382; 257/E47.001; 257/E21.004

(57) ABSTRACT

Embodiments of the invention set forth a nonvolatile memory element with a novel variable resistance layer and methods of forming the same. The novel variable resistance layer includes a metal-rich host oxide that operates with a reduced switching voltage and current and requires significantly reduced forming voltage when manufactured. In some embodiments, the metal-rich host oxide is deposited using a modified atomic layer deposition (ALD) process. In other embodiments, the metal-rich host oxide is formed by depositing a metal-containing coupling layer on a host oxide and thermally processing both layers to create a metal-rich composite host oxide with a higher concentration of oxygen vacancies.

### BACKGROUND

1. Field of the Invention

This invention relates to nonvolatile resistive memory elements, and more particularly, to defect enhancement of a switching layer in a nonvolatile resistive memory element.

2. Description of the Related Art

Nonvolatile memory elements are used in devices requiring persistent data storage, such as digital cameras and digital music players, as well as in computer systems. Electrically-erasable programmable read only memory (EPROM) and NAND flash are nonvolatile memory technologies currently in use. However, as device dimensions shrink, scaling issues pose challenges for traditional nonvolatile memory technology. This has led to the investigation of alternative nonvolatile memory technologies, including resistive switching nonvolatile memory.

Resistive-switching-based nonvolatile memory is formed using memory elements that are bistable, i.e., having two stable states with different resistances. A bistable memory element can be placed in a high resistance state or a low resistance state by application of suitable voltages or currents. Voltage pulses are typically used to switch the bistable memory element from one resistance state to the other. Subsequently, nondestructive read operations can be performed on the memory element to ascertain the value of a data bit that is stored therein.

As resistive switching memory device sizes shrink, it is important to reduce the required currents and voltages that are necessary to reliably set, reset and/or determine the desired “on” and “off” states of the device, thereby minimizing power consumption of the device, resistive heating of the device, and cross-talk between adjacent devices. In light of the above, there is a need in the art for nonvolatile resistive switching memory devices having reduced current and voltage usage.

### SUMMARY

Embodiments of the invention set forth a nonvolatile resistive memory element that includes a metal-rich host oxide having an enhanced defect distribution and methods of forming the same. The metal-rich host oxide is formed according to various embodiments of the invention.

According to one embodiment of the present invention, a nonvolatile memory element comprises a first layer operable as an electrode layer, a second layer operable as an electrode layer, a third layer operable as a variable resistance layer that is disposed between the first layer and the second layer and comprises an oxide of a metal, and a fourth layer that is disposed adjacent to the third layer and comprises a substantially oxide-free layer of the metal.

According to another embodiment of the present invention, a nonvolatile memory element comprises a first layer operable as an electrode layer, a second layer operable as an electrode layer, a third layer operable as a variable resistance layer that is disposed between the first layer and the second layer and comprises an oxide of a first metal, and a fourth layer that is disposed adjacent to the third layer and comprises a second metal, wherein a reaction between the oxide of the first metal and the second metal produces an oxide of the second metal, the chemical reaction having a Gibbs free energy of formation that is less than zero.

According to another embodiment of the present invention, a nonvolatile memory element comprises a first layer operable as an electrode layer, a second layer operable as an electrode layer, a third layer operable as a variable resistance layer that is disposed between the first layer and the second layer and comprises an oxide of a first metal, and a fourth layer that is disposed adjacent to the third layer and comprises a second metal, wherein an oxide of the second metal has a Gibbs free energy of formation that is more negative than a Gibbs free energy of formation of the oxide of the first metal.

According to another embodiment of the present invention, a method of forming a nonvolatile memory element includes the steps of forming a first layer operable as an electrode layer of the nonvolatile memory element, forming a second layer above the first layer, wherein the second layer is operable as a variable resistance layer of the nonvolatile memory element and comprises an oxide of a metal, forming a third layer such that the third layer is ultimately disposed adjacent to the second layer, wherein the third layer comprises a substantially oxide-free layer of the metal, thermally annealing the third layer, and forming a fourth layer above the second layer and the third layer, wherein the fourth layer is operable as an electrode layer of the nonvolatile memory element.

According to another embodiment of the present invention, a method of forming a nonvolatile memory element includes the steps of forming a first layer operable as an electrode layer of the nonvolatile memory element, forming a second layer above the first layer, wherein the second layer is operable as a variable resistance layer of the nonvolatile memory element and comprises an oxide of a first metal, forming a third layer that comprises a second metal such that the third layer is ultimately disposed adjacent to the second layer, wherein an oxide of the second metal has a Gibbs free energy of formation that is more negative than a Gibbs free energy of formation of the oxide of the first metal, thermally annealing the third layer, and forming a fourth layer above the second layer and the third layer, wherein the fourth layer is operable as an electrode layer of the nonvolatile memory element.

According to another embodiment of the present invention, a method of forming a nonvolatile memory element includes the steps of forming a first layer operable as an electrode layer of the nonvolatile memory element, depositing a metal-rich oxide of a first metal above the first layer using an atomic layer deposition process, wherein the metal rich oxide forms a second layer operable as a variable resistance layer of the nonvolatile memory element, and forming a third layer above the second layer, wherein the third layer is operable as an electrode layer of the nonvolatile memory element.

### BRIEF DESCRIPTION OF THE DRAWINGS

So that the manner in which the above recited features of embodiments of the invention can be understood in detail, a more particular description of embodiments of the invention, briefly summarized above, may be had by reference to the appended drawings. It is to be noted, however, that the appended drawings illustrate only typical embodiments of this invention and are therefore not to be considered limiting of its scope, for the invention may admit to other equally effective embodiments.

FIG. 1 is a perspective view of a memory array of memory devices, configured according to embodiments of the invention.

FIG. 2A schematically illustrates one embodiment of memory array 100 having a plurality of memory devices 200 connected together to form part of a high-capacity nonvolatile memory array that, together with memory read and write circuitry and other peripheral devices, constitutes a memory chip.

FIG. 2B schematically illustrates a memory device configured to allow current to flow through the memory device in a forward direction, according to embodiments of the invention.

FIG. 3 schematically illustrates an exemplary plots of measured log current (I) values versus applied voltages (V) of an exemplary embodiment of a memory device having a resistive switching memory element.

FIG. 4 is a schematic cross-sectional view of a memory device formed from a series of deposited layers, including a novel variable resistance layer, according to embodiments of the invention.

FIG. 5 illustrates a process sequence for forming a memory device, according to embodiments of the invention.

FIG. 6 illustrates a process sequence for forming a metal-rich variable resistance layer, according to embodiments of the invention.

FIGS. 7A-7C are cross-sectional views of a memory device during the execution of the process sequence set forth in FIG. 6, according to embodiments of the invention.

FIG. 8 illustrates a process sequence for forming a metal-rich variable resistance layer, according to embodiments of the invention.

FIGS. 9A-9C are cross-sectional views of a memory device during the execution of the process sequence set forth in FIG. 8, according to embodiments of the invention.

FIG. 10 illustrates a process sequence for forming a metal-rich variable resistance layer using a modified ALD process, according to embodiments of the invention.

FIG. 11 is a graph illustrating forming voltages V_{FORM} measured for three different sets of memory devices that are configured according to embodiments of the invention.

FIG. 12 is a graph illustrating a comparison of minimum set voltages V_{SET} required for various resistive switching memory devices, including prior art memory devices and memory devices configured according to embodiments of the invention.

For clarity, identical reference numbers have been used, where applicable, to designate identical elements that are common between figures. It is contemplated that features of one embodiment may be incorporated in other embodiments without further recitation.

### DETAILED DESCRIPTION

Materials used as the switching layer of a nonvolatile resistive memory element are generally required to have bistable electrical switching properties and, ideally, can be operated with low switching current and formed with a minimal forming voltage. Embodiments of the invention set forth a nonvolatile memory element with a novel variable resistance layer and methods of forming the same. The novel variable resistance layer includes a metal-rich host oxide that operates with a reduced switching voltage and current and requires significantly reduced forming voltage when manufactured. In some embodiments, the metal-rich host oxide is deposited using a modified atomic layer deposition (ALD) process. In other embodiments, the metal-rich host oxide is formed by depositing a metal-containing coupling layer on a host oxide and thermally processing both layers to create a metal-rich composite host oxide with a higher concentration of oxygen vacancies.

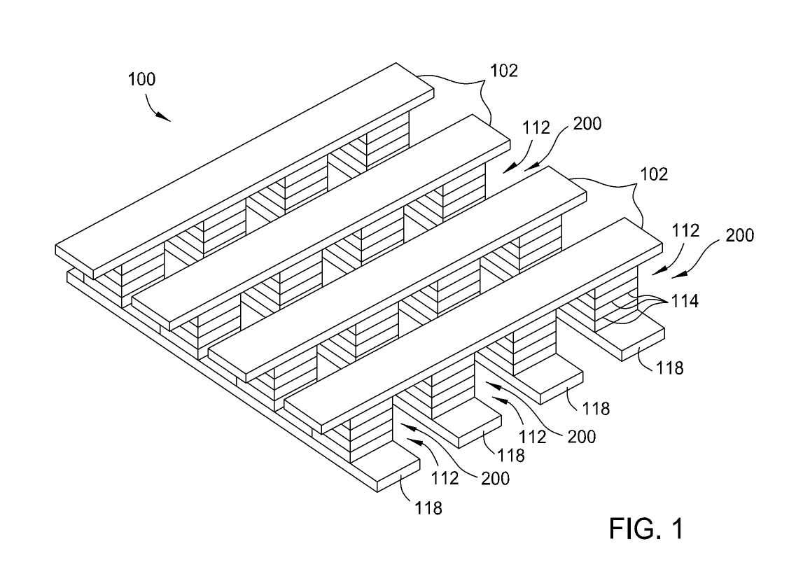

FIG. 1 is a perspective view of a memory array 100 of memory devices 200, configured according to embodiments of the invention. Memory array 100 may be part of a larger memory device or other integrated circuit structure, such as a system-on-a-chip type device. Memory array 100 may be formed as part of a high-capacity nonvolatile memory integrated circuit, which can be used in various electronic devices, such as digital cameras, mobile telephones, hand-held computers, and music players. For clarity, memory array 100 is illustrated as a single layer memory array structure. However, memory arrays such as memory array 100 can also be stacked in a vertical fashion to make multilayer memory array structures.

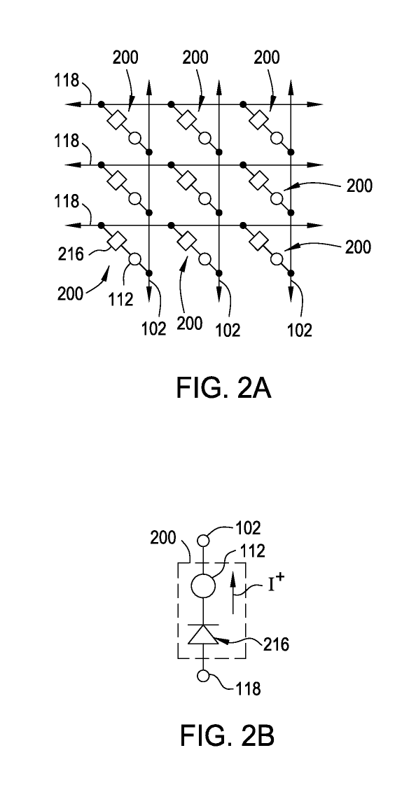

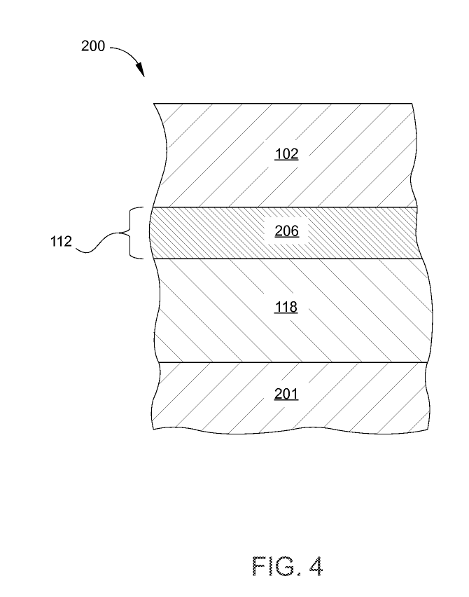

Each of memory devices 200 comprises a nonvolatile resistive switching memory device, such as a resistive random access memory (ReRAM) device. Memory device 200 comprises a novel memory element 112 that may be formed from one or more material layers 114. Material layers 114 include a novel variable resistance layer comprising a metal-rich host oxide that operates with a reduced switching voltage and current and requires significantly reduced forming voltage when manufactured. The novel variable resistance layer is described below in conjunction with FIG. 4. In some embodiments, memory device 200 also includes a current steering device, which is described below in conjunction with FIGS. 2A and 2B.

Read and write circuitry (not shown) is connected to memory devices 200 using electrodes 102 and electrodes 118. Electrodes 102 and electrodes 118, which are sometimes referred to as “bit lines” and “word lines,” are tied together for multiple cells or an array via interconnects and are used to read and write data into memory elements 112 in memory devices 200. Individual memory devices 200 or groups of memory devices 200 can be addressed using appropriate sets of electrodes 102 and electrodes 118.

FIG. 2A schematically illustrates one embodiment of memory array 100 having a plurality of memory devices 200 connected together to form part of a high-capacity nonvolatile memory array that, together with memory read and write circuitry and other peripheral devices, constitutes a memory chip. In accordance with one embodiment of the invention, each of the memory devices 200 may include one resistor structure 220, one resistive switching memory element 112, and one current steering element 216 (e.g., a diode-type current steering device) that are connected to at least one of the electrodes 102 and at least one of the electrodes 118. Each of the memory devices 200 can be accessed individually using appropriate sets of discrete word-lines and bit-lines, which are comprised by at least a portion of the electrodes 102 and 118.

In some embodiments, current steering device 216 may include two or more layers of semiconductor material, such as two or more doped silicon layers, that are configured to allow or inhibit the current flow in different directions through the memory element 112. In addition, read and write circuitry (not shown) is coupled to memory device 200 via electrodes 102 and electrodes 118 as shown. Generally, such read and write circuitry is configured to both sense the resistance state and set the resistance state of memory device 200.

FIG. 2B schematically illustrates memory device 200 configured to allow current to flow through memory device 200 in a forward direction (“I⁺”), according to embodiments of the invention. However, due to the design of current steering device 216, a reduced current can also flow in the opposing direction through the device by the application of a reverse bias to electrodes 102 and electrodes 118.

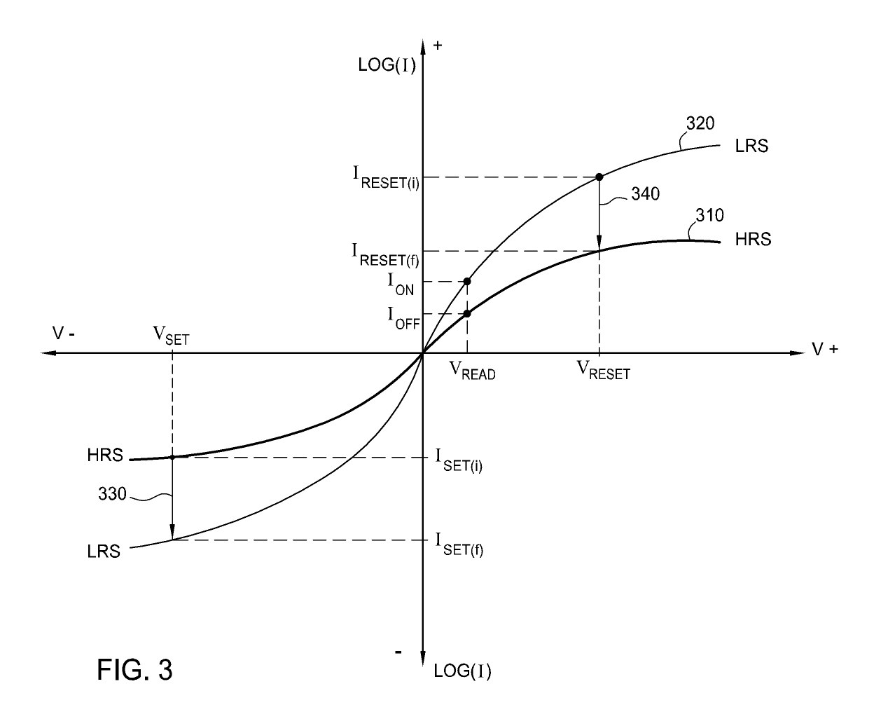

FIG. 3 schematically illustrates an exemplary plot of measured log current (I) values versus applied voltages (V) of an exemplary embodiment of memory device 200 having a resistive switching memory element 112. The resistive switching memory element may be placed in two stable resistance states: a low-resistance-state (LRS), following the I-V curve of a LRS curve 320, or a high-resistance-state (HRS), following the I-V curve of a HRS curve 310.

In general, by sweeping the voltage applied to the electrode layers 102 and 118 between two applied voltages (e.g., between V_{SET} (e.g., −3 volts) and V_{RESET} (e.g., +4 volts)) while memory device 200 is in the low resistance state, the LRS curve 320 is obtained. On the other hand, by sweeping the voltage applied to the electrode layers 102 and 118 between two applied voltages (e.g., between V_{SET} and V_{RESET}) while memory device 200 is in the high resistance state, the HRS curve 310 is obtained. Accordingly, resistive switching memory element 112 may either be in a high resistance state (HRS) or a low resistance state (LRS). Resistive switching memory element 112 within memory device 200 can be selectively chosen by read-and-write circuitry for memory array 100 to switch between its resistance states. Current steering element 216 is used to regulate (e.g., allow or inhibit, etc.) current such that current will flow through only the desired memory cells when the appropriate set of word-lines and bit-lines and/or electrodes are selected.

During a “set” operation, because of the physical and electrical characteristics of variable resistance layer 206, resistive switching memory element 112 of memory device 200 can switch from the HRS to the LRS (e.g., following the path of an arrow 330), when a “set” switching pulse (e.g., a pulse at V_{SET} voltage level) is applied and delivered through the memory device. By applying the “set” switching pulse to memory device 200, the current flowing through memory device 200 can shift from the initial “set” current level, I_{SET(i)}, to the final “set” current level, I_{SET(f)}, according to the arrow 330, due to the change in the resistance of the variable resistance layer 206.

In addition, during a “reset” operation, variable resistance layer 206 can function to switch from the LRS to the HRS (e.g., following the path of arrow 340), when a “reset” switching pulse (e.g., a pulse at V_{RESET} voltage level) is delivered to memory device 200. The current flowing through memory device 200 can shift from the initial “reset” current level, I_{RESET(i)}, to the final “reset” current level, I_{RESET(f)}, due to the change in the resistance of variable resistance layer 206.

During a read operation, the logic state of resistive switching memory element 112 in memory device 200 can be sensed by applying a sensing voltage (i.e., a “read” voltage V_{READ} as shown in FIG. 3, (e.g., applying a sense pulse at about +0.5 to +1.5 volts (V) voltage level)), to an appropriate set of electrodes 102 and 118. Depending on its history, a resistive switching memory element 112 addressed in this way may be either in a high resistance state (HRS) or a low resistance state (LRS). The resistance of resistive switching memory element 112 therefore determines what digital data is being stored by resistive switching memory element 112. If resistive switching memory element 112 is in the low resistance state (LRS), for example, resistive switching memory element 112 may be said to contain a logic one (i.e., a “1” bit). If, on the other hand, resistive switching memory element 112 is in the high resistance state (HRS), resistive switching memory element 112 may be said to contain a logic zero (i.e., a “0” bit).

During a programming operation, the state of a memory element can be changed by application of suitable programming signals to appropriate sets of the electrode layers 102 and 118. In one example, initially, resistive switching memory element 112 may be in a high resistance state (e.g., storing a logic “zero”). The high resistance state (HRS) of resistive switching memory element 112 can be sensed by read circuitry (not shown) for memory array 100 using the electrodes 102 and 118. For example, such read circuitry may apply a read voltage pulse at a V_{READ} voltage level (e.g., +0.5V) to resistive switching memory element 112, and can sense the resulting “off” current level (I_{OFF}) that flows through resistive switching memory element 112.

Next, when it is desired to store a logic “one” in memory device 200, resistive switching memory element 112 needs to be placed into its low resistance state (LRS). This may be accomplished by using write circuitry (not shown) for memory array 100 to apply a “set” voltage pulse at a V_{SET} (e.g., −2 V to −4 V) voltage level across the electrodes 102 and 118. In one configuration, applying a negative voltage pulse at a V_{SET} voltage level to resistive switching memory element 112 causes resistive switching memory element 112 to switch to its low resistance state (LRS), following the arrow 330. Resistive switching memory element 112 is changed so that, following the removal of the “set” voltage pulse, V_{SET}, resistive switching memory element 112 is characterized to be in a low resistance state (LRS). It is believed that the change in the resistance state of resistive switching memory element 112 may be because the reverse biasing of the device cause traps formed in a variable resistance layer in the memory element to be redistributed or filled (i.e., “trap-mediated”) during this process. V_{SET} and V_{RESET} are generally referred to as “switching voltages” herein. The low resistance state (LRS) of the resistive switching memory element can be sensed using the read circuitry for memory array 100. When a read voltage pulse at the V_{READ} level is applied to resistive switching memory element 112, the read circuitry senses the relatively high “on” current value (I_{ON}), indicating that resistive switching memory element 112 is in its low resistance state (LRS).

When it is desired to store a logic “zero” in the memory cell 200, resistive switching memory element 112 can once again be placed in its high resistance state (HRS) by applying a positive “reset” voltage pulse at a V_{RESET} (e.g., +2 V to +5 V) voltage level to the memory device. When write circuitry for memory array 100 applies V_{RESET} to resistive switching memory element 112, it switches to its high resistance state (HRS), following the arrow 340. When the reset voltage pulse, V_{RESET}, is removed from resistive switching memory element 112, resistive switching memory element 112 can once again be tested whether it is in the high resistance state (HRS) by applying a read voltage pulse at the V_{READ} voltage level.

While the discussion of the resistive switching memory element herein primarily provides bipolar switching examples, some embodiments of the resistive switching memory elements may use unipolar switching, where the “set” and “reset” voltage pulses have the same polarity, without deviating from the scope of the invention described herein.

It is believed that the change in the resistive state of the memory element 112 may be “trap-mediated,” i.e., changes in resistive state are due to the redistribution or filling of traps or defects in a variable resistance layer of memory element 112 when voltage is applied across memory device 200. When the variable resistance layer comprises a metal oxide, which is sometimes referred to as a host oxide, the defects or traps are generally thought to be oxygen vacancies formed during the deposition and/or the initial “burning-in” (or “forming”) of the variable resistance layer. Such oxygen vacancies are likely created in the variable resistance layer by making the metal/oxygen ratio larger than that for exact stoichiometry in the variable resistance layer. Alternatively, in a substantially stoichiometric variable resistance layer, such oxygen vacancies may also be formed by the displacement of oxygen atoms from their atomic sites, for example by reduction of the host oxide material. Various embodiments of the invention are provided in which the host oxide material of a variable resistance layer is enhanced with a higher concentration of oxygen vacancies in one of these ways. Consequently, the variable resistance layer has been shown to be more amenable to switching and to require a reduced forming voltage.

FIG. 4 is a schematic cross-sectional view of memory device 200 formed from a series of deposited layers, including a novel variable resistance layer 206, according to embodiments of the invention. In the embodiment illustrated in FIG. 4, memory device 200 is formed over, or integrated with and disposed over, portions of a surface of a substrate 201 (e.g., a silicon substrate or an SOI substrate). It is noted that relative directional terms used herein with regard to embodiments of the invention are for purposes of description only, and do not limit the scope of the invention. Specifically, directional terms such as “over,” “above,” “under,” and the like are used under the assumption that substrate 201 on which embodiments are formed is a “bottom” element and is therefore “under” elements of the invention formed thereon.

In the embodiment illustrated in FIG. 4, memory device 200 comprises a memory element 112 disposed between electrodes 102, 118. Memory element 112 is a nonvolatile resistive memory element that includes variable resistance layer 206. In other embodiments, memory device 200 further comprises an optional intermediate electrode and optional current steering device 216 (illustrated in FIGS. 2A and 2B) disposed between electrode 118 and variable resistance layer 206.

Electrodes 102, 118 are formed from conductive materials that have a desirable work function tailored to the bandgap of the material making up variable resistance layer 206. In some configurations, electrodes 102, 118 are formed from different materials so that electrodes 102, 118 have a work function that differs by a desired value, e.g., 0.1 eV, 0.5 eV, 1.0 eV, etc. For example, in one embodiment, electrode 102 is comprised of TiN, which has a work function of 4.5-4.6 eV, while electrode 118 can be n-type polysilicon, which has a work function of approximately 4.1-4.15 eV. Other electrode materials suitable for use in electrode 102 and/or electrode 118 include p-type polysilicon (4.9-5.3 eV), n-type polysilicon, transition metals, transition metal alloys, transition metal nitrides, transition metal carbides, tungsten (4.5-4.6 eV), tantalum nitride (4.7-4.8 eV), molybdenum oxide (˜5.1 eV), molybdenum nitride (4.0-5.0 eV), iridium (4.6-5.3 eV), iridium oxide (˜4.2 eV), ruthenium (˜4.7 eV), and ruthenium oxide (˜5.0 eV). Other potential electrode materials include a titanium/aluminum alloys (4.1-4.3 eV), nickel (˜5.0 eV), tungsten nitride (˜4.3-5.0 eV), tungsten oxide (5.5-5.7 eV), aluminum (4.2-4.3 eV), copper or silicon-doped aluminum (4.1-4.4 eV), copper (˜4.5 eV), hafnium carbide (4.8-4.9 eV), hafnium nitride (4.7-4.8 eV), niobium nitride (˜4.95 eV), tantalum carbide (approximately 5.1 eV), tantalum silicon nitride (˜4.4 eV), titanium (4.1-4.4 eV), vanadium carbide (˜5.15 eV), vanadium nitride (˜5.15 eV), and zirconium nitride (˜4.6 eV). In some embodiments, electrode 102 is a metal, metal alloy, metal nitride or metal carbide formed from an element selected from a group of materials consisting of titanium (Ti), tungsten (W), tantalum (Ta), cobalt (Co), molybdenum (Mo), nickel (Ni), vanadium (V), hafnium (Hf) aluminum (Al), copper (Cu), platinum (Pt), palladium (Pd), iridium (Ir), ruthenium (Ru), and combinations thereof. In one example, electrode 102 comprises a metal alloy selected from the group of a titanium/aluminum alloy (TiₓAl_{y}), or a silicon-doped aluminum (AISi).

Variable resistance layer 206 comprises a dielectric material that can be switched between two or more stable resistive states. The dielectric material comprises a non-stoichiometric, metal-rich host oxide material that is enhanced with an increased concentration of oxygen vacancies. Thus, variable resistance layer 206 can operate with lower switching voltage and can be “electrically” formed with a reduced forming voltage. In some embodiments, variable resistance layer 206 has a thickness of between about 10 Å and about 100 Å, and comprises one or more oxides of a transition metal, including but not limited to hafnium (Hf), zirconium (Zr), titanium (Ti), tantalum (Ta), aluminum (Al), lanthanum (La), yttrium (Y), dysprosium (Dy), and ytterbium (Yb).

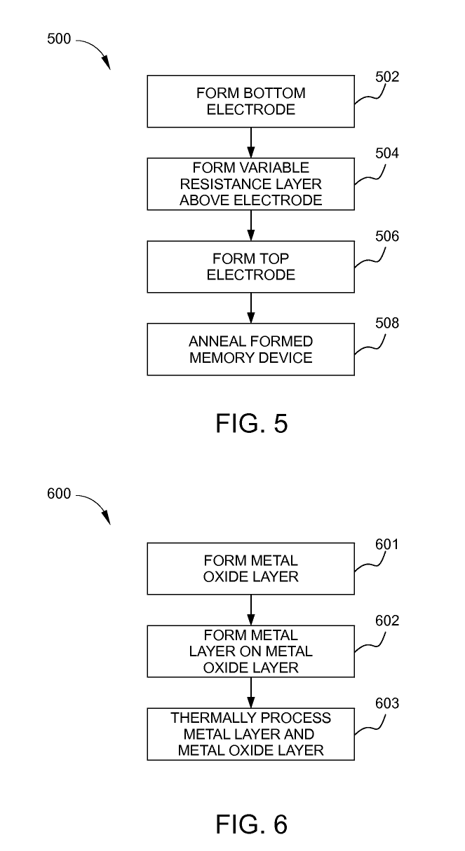

FIG. 5 sets forth a flowchart of method steps in a process sequence 500 for forming memory device 200, according to embodiments of the invention. Although the method steps are described in conjunction with memory device 200 in FIG. 4, persons skilled in the art will understand that formation of other resistive switching memory devices using process sequence 500 is within the scope of the invention.

As shown, method 500 begins at step 502, in which electrode 118 is formed on substrate 201 using one or more of the materials listed above in conjunction with FIG. 4. In one embodiment, electrode 118 is a highly doped polysilicon layer that is formed on substrate 201 using a conventional CVD polysilicon deposition technique. In one embodiment, electrode 118 is between about 50 and about 1000 Å thick.

In step 504, variable resistance layer 206 is formed on or above electrode 118. In some embodiments, variable resistance layer 206 is formed directly on electrode 118 as shown in FIG. 4. In other embodiments, variable resistance layer 206 is formed on one or more intervening layers formed on electrode 118. Variable resistance layer 206 is formed using one or more deposition processes, so that variable resistance layer 206 includes a non-stoichiometric, metal-rich host oxide material that is enhanced with an increased concentration of oxygen vacancies. Embodiments of the invention include various methods of depositing variable resistance layer 206, and are described below in conjunction with FIGS. 6-10.

In step 506, electrode 102 is formed on or above variable resistance layer 206 as shown in FIG. 4 using one or more of the materials suitable for electrode 102 listed above in conjunction with FIG. 4. In some embodiments, electrode 102 is formed directly on variable resistance layer 206 as shown in FIG. 4. In other embodiments, electrode 102 is formed on one or more intervening layers formed on variable resistance layer 206. Electrode 102 may be formed using a deposition process, such as a PVD, CVD, ALD or other similar process. In one embodiment, electrode 102 is between about 50 Å and 1000 Å thick.

In step 508, formed memory device 200 is thermally processed, e.g., via an anneal process. Temperature and duration of the anneal process is a function of the configuration of memory device 200 as well as the materials included in memory device 200. For example, in some embodiments, the anneal process takes place at temperatures between about 550° C. and 1000° C. Duration of the anneal process can also vary greatly, e.g. varying between about 30 seconds and 30 minutes depending on the configuration of memory device 200. Furthermore, vacuum anneals, oxygen anneals, anneals using gas mixtures, such as a hydrogen/argon mixture, and other anneal processes known in the art fall within the scope of the invention. Similarly, multiple thermal processing steps may be performed on memory device 200 without exceeding the scope of the invention. For example, a thermal process may be performed during or after multiple steps of method 500.

In one embodiment, variable resistance layer 206 includes a metal-rich host oxide material that is formed by depositing a metal-containing coupling layer adjacent to a host oxide layer, where the coupling layer comprises the same metal as that in the host oxide layer. A subsequent thermal anneal process creates a metal-rich composite host oxide in variable resistance layer 206.

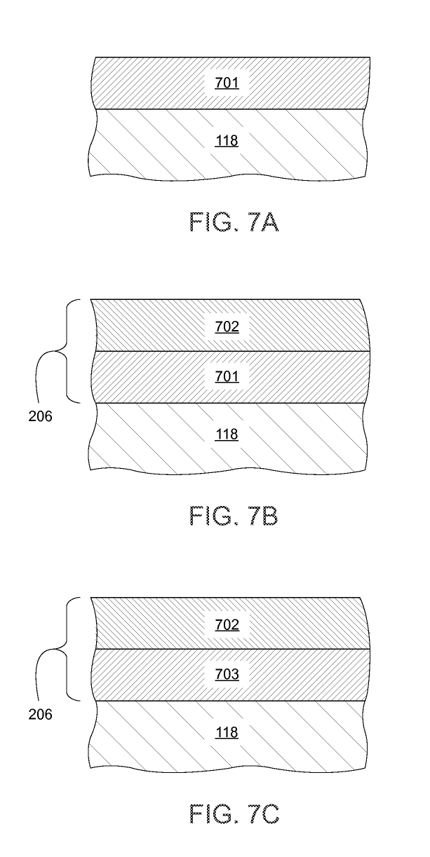

FIG. 6 sets forth a flowchart of method steps in a process sequence 600 for forming a metal-rich variable resistance layer 206, according to embodiments of the invention. FIGS. 7A-7C sequentially illustrate cross-sectional views of memory device 200 during the execution of process sequence 600, according to embodiments of the invention. Although the method steps are described in conjunction with memory device 200 in FIG. 4, persons skilled in the art will understand that the formation of other resistive switching memory devices using process sequence 600 is within the scope of the invention.

As shown, method 600 begins at step 601, in which a metal oxide (MO_{X}) layer 701 is formed on a desired surface, such as the surface of electrode 118. Metal oxide layer 701 (illustrated in FIG. 7A) is a host oxide layer for variable resistance layer 206 and may comprise any of the materials presented above as suitable for variable resistance layer 206. Any technically feasible deposition process known in the art may be used in step 601 to deposit metal oxide layer 701, including ALD, chemical vapor deposition (CVD), and the like. The thickness of metal oxide layer 701 may be between about 10 Å and about 100 Å.

In step 602, a metal layer 702 is formed on metal oxide layer 701, as illustrated in FIG. 7B. Metal layer 702 includes the same metal that is contained in metal oxide layer 701. For example, in one embodiment, metal oxide layer 701 comprises a hafnium oxide layer and metal layer 702 comprises a hafnium layer. In one embodiment, the thickness of metal layer 702 is either equal to or less than the thickness of metal oxide layer 701, since it is believed that an increased thickness in metal layer 702 beyond a certain threshold does not generally provide increased benefits to the properties of metal oxide layer 701. Any technically feasible deposition process known in the art may be used in step 602 to deposit metal layer 702, including physical vapor deposition (PVD), i.e., “sputtering”, evaporation, ALD, and the like.

In step 603, metal oxide layer 701 and metal layer 702 are thermally processed, to create an enhanced metal oxide layer 703, as illustrated in FIG. 7C. Enhanced metal oxide layer 703 comprises a metal-rich composite host oxide material formed by the diffusion of metal atoms in metal layer 702 into metal oxide layer 701. The metal-rich nature of enhanced metal oxide layer 703 provides increased oxygen vacancies that make variable resistance layer 206 more readily “electrically” formed (i.e., formed by a lower forming voltage), and more amenable to switching (i.e., able to operate at a lower switching voltage). In some embodiments, enhanced metal oxide layer 703 is a substantially homogeneous layer of metal-rich metal oxide material. In other embodiments, enhanced metal oxide layer 703 may include a non-uniform distribution of metal-rich material, such as a continuous gradient or a metal-rich portion and a stoichiometric portion.

In some embodiments, the thermal processing in step 603 may be the thermal processing in step 508 of method 500. In other embodiments, the thermal processing in step 603 may be a separate thermal processing step. The thermal processing of step 603 may be a single-step, multi-step, and/or ramped process. The duration and temperature of the thermal processing of step 603 depend on the specific metal and thickness of variable resistance layer 206 formed in steps 601 and 602.

While method 600 describes the formation of a metal-rich variable resistance layer 206 by depositing metal layer 702 onto metal oxide layer 701, one of skill in the art will appreciate that, in some embodiments, metal layer 702 may be deposited first, and metal oxide layer 701 may be deposited onto metal layer 702 without exceeding the scope of the invention.

In one embodiment, variable resistance layer 206 includes a metal-rich host oxide material that is formed by depositing a defect enhancement layer adjacent on a host oxide layer, where the defect enhancement layer comprises a different metal and/or metal oxide than the materials found in the host oxide layer. A subsequent thermal anneal process reduces the host oxide to form a metal-rich host oxide material, while a corresponding oxidation reaction occurs in the defect enhancement layer.

According to embodiments of the invention, the material of the defect enhancement layer is selected based on a thermodynamic property of the host oxide layer known as the Gibbs free energy of formation (Δ_{f}G°). The standard Gibbs free energy of formation of a chemical compound is generally defined as the change of Gibbs free energy that accompanies the formation of 1 mole of that compound from its component elements at their standard states. As such, the Gibbs free energy of formation of a chemical compound is a convenient criterion of the spontaneity for different chemical processes, where a lower (i.e., more negative) Gibbs free energy denotes a higher chemical affinity between the constituent elements making up the chemical compound. By using a material for the defect enhancement layer that is selected to have a more negative Gibbs free energy of formation than the Gibbs free energy of formation of the host oxide material, oxygen atoms may be drawn from the host oxide material in variable resistance layer 206, thereby creating a metal-rich host oxide material.

In some embodiments of the invention, a metal oxide is selected for the defect enhancement layer that has a more negative Gibbs free energy of formation than the Gibbs free energy of formation of the metal oxide material included in the host oxide layer. In other embodiments of the invention, a second metal is selected for the defect enhancement layer that, when in the form of an oxide, has a more negative Gibbs free energy of formation than the Gibbs free energy of formation of the metal oxide material included in the host oxide layer. For example, according to one embodiment of the invention, when the host oxide layer in variable resistance layer 206 comprises a hafnium oxide layer (Δ_{f}G°=−1088.2 kJ/mol), suitable materials for the defect enhancement layer include any metals whose oxide have a Gibbs free energy of formation that is less than −1088.2 kJ/mol or any metal oxides having a Gibbs free energy of formation that is less than −1088.2 kJ/mol. Specifically, in this example embodiment, suitable metals include aluminum (Al), lanthanum (La), and yttrium (Y), since the Gibbs free energy of formation of aluminum oxide (Al₂O₃) is −1582.3 kJ/mol, the Gibbs free energy of formation of lanthanum oxide (La₂O₃) is −1705.8 kJ/mol, and the Gibbs free energy of formation of yttrium oxide (Y₂O₃) is −1816.7 kJ/mol. For the reasons stated above, suitable metal oxides include aluminum oxide, lanthanum oxide, and yttrium oxide.

In other embodiments, a metal selected for the defect enhancement layer is capable of undergoing a chemical reaction with the host oxide material that is energetically favorable and can therefore capture or “scavenge” oxygen from the host oxide layer. Specifically, the chemical reaction between the host oxide and the metal of the defect enhancement layer has a Gibbs free energy that is less than zero and produces an oxide of the second metal, and reduces a portion of the host oxide to metal at sufficiently elevated temperatures, thereby forming a metal-rich host oxide material that provides increased oxygen vacancies. In such embodiments, the metal (M2) selected for the defect enhancement layer satisfies the following chemical equation, where M1 O_{X} is the host oxide material:

M1O_{X}+M2→M1+M2O_{X} where ΔG<0

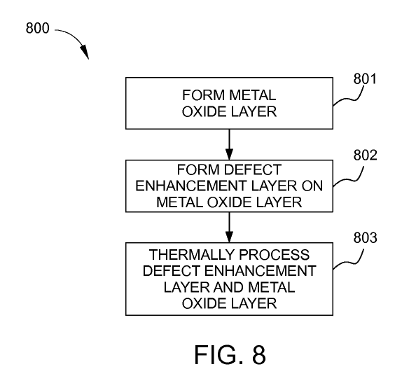

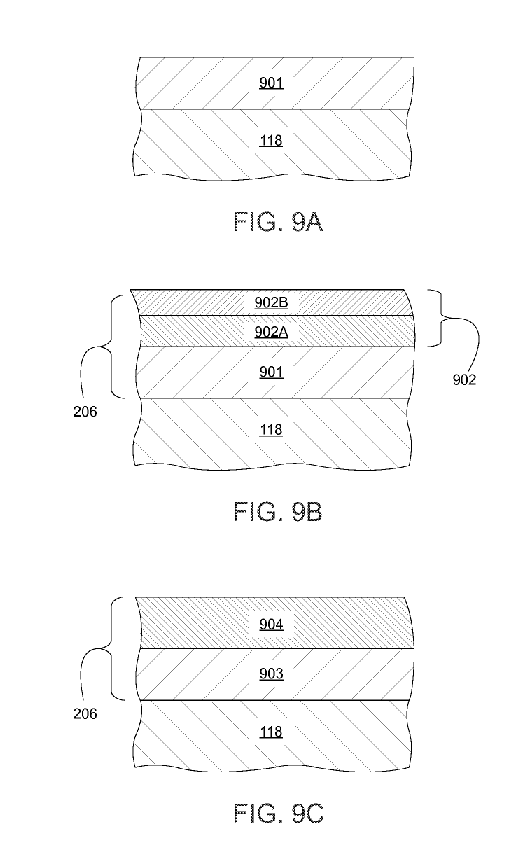

FIG. 8 sets forth a flowchart of method steps in a process sequence 800 for forming a metal-rich variable resistance layer 206, according to embodiments of the invention. FIGS. 9A-9C sequentially illustrate cross-sectional views of memory device 200 during the execution of process sequence 800, according to embodiments of the invention. Although the method steps are described in conjunction with memory device 200 in FIG. 4, persons skilled in the art will understand that the formation of other resistive switching memory devices using process sequence 800 is within the scope of the invention.

As shown, method 800 begins at step 801, in which a metal oxide (MO_{X}) layer 901 is formed on a desired surface, such as the surface of electrode 118. Metal oxide layer 901 (illustrated in FIG. 9A) is a host oxide layer for variable resistance layer 206 and may be formed from any of the materials presented above as suitable for variable resistance layer 206. Any technically feasible deposition process known in the art may be used in step 801 to deposit metal oxide layer 901, including ALD, chemical vapor deposition (CVD), and the like. The thickness of metal oxide layer 901 may be between about 10 Å and about 100 Å.

In step 802, a defect enhancement layer 902 is formed on metal oxide layer 901, as illustrated in FIG. 9B. Defect enhancement layer 902 includes a second metal layer, a second metal oxide layer, or a combination of both, where the second metal is different than the metal contained in metal oxide layer 901. Furthermore, the second metal and/or second metal oxide in defect enhancement layer 902 are selected based on the Gibbs free energy of formation of the metal oxide in metal oxide layer 901 and on the Gibbs free energy of formation of an oxide of the second metal. Specifically, the Gibbs free energy of formation of the metal oxide of the second metal is more negative than the Gibbs free energy of formation of the metal oxide in metal oxide layer 901. For example, in one embodiment, metal oxide layer 901 comprises a hafnium oxide layer and defect enhancement layer 902 comprises an aluminum, hafnium, lanthanum, titanium, yttrium, zirconium, aluminum oxide, lanthanum oxide, or yttrium oxide layer. In another example, metal oxide layer 901 comprises a zirconium oxide layer and defect enhancement layer 902 comprises a hafnium, aluminum, lanthanum, titanium, yttrium, zirconium, hafnium oxide, aluminum oxide, lanthanum oxide, or yttrium oxide layer. In some embodiments, defect enhancement layer 902 formed in step 802 includes both a second metal layer and a second metal oxide layer. For example, in one embodiment, second metal layer 902A is formed on or adjacent to metal oxide layer 901, and a second metal oxide layer 902B is formed adjacent to second metal layer 902A.

In one embodiment, the thickness of defect enhancement layer 902 is either equal to or less than the thickness of metal oxide layer 901, since it is believed that an increased thickness in defect enhancement layer 902 beyond a certain threshold does not generally provide increased benefits to the properties of metal oxide layer 901. Any technically feasible deposition process known in the art may be used in step 802 to deposit defect enhancement layer 902, including PVD, evaporation, ALD, and the like.

In step 803, metal oxide layer 901 and defect enhancement layer 902 are thermally processed to create a slightly reduced metal oxide layer 903 and a slightly oxidized defect enhancement layer 904, as illustrated in FIG. 9C. Reduced metal oxide layer 903 comprises a metal-rich host oxide material formed by the diffusion of oxygen atoms from metal oxide layer 901 into defect enhancement layer 902. The metal-rich nature of reduced metal oxide layer 903 provides increased oxygen vacancies that make variable resistance layer 206 more readily formed (i.e., formed by a lower forming voltage), and more amenable to switching (i.e., able to operate at a lower switching voltage).

In some embodiments, the thermal processing in step 803 may be the thermal processing in step 508 of method 500. In other embodiments, the thermal processing in step 803 may be a separate thermal processing step. The thermal processing of step 803 may be a single-step, multi-step, and/or ramped process. The duration and temperature of the thermal processing of step 803 depend on the specific metal and thickness of variable resistance layer 206 formed in steps 801 and 802.

While method 800 describes the formation of a metal-rich variable resistance layer 206 by first depositing defect enhancement layer 902 onto metal oxide layer 901, one of skill in the art will appreciate that, in some embodiments, defect enhancement layer 902 may be deposited first, and metal oxide layer 901 may be deposited onto defect enhancement layer 902 without exceeding the scope of the invention.

In one embodiment, variable resistance layer 206 includes a metal-rich host oxide material that is formed by a modified ALD process. Generally, ALD processes for depositing metal oxides form alternating monolayers of metal and oxygen atoms on a desired surface. According to embodiments of the inventᵢon, the adsorption of the metal precursor relative to the adsorption of the oxidant is increased, so that the modified ALD process forms a non-stoichiometric metal oxide layer. The increased oxygen vacancies present in such a nonstoichiometric metal oxide layer may serve as filament paths in the variable resistance layer 206 that reduce the forming and switching voltages required to operate the resistive switching memory device as desired.

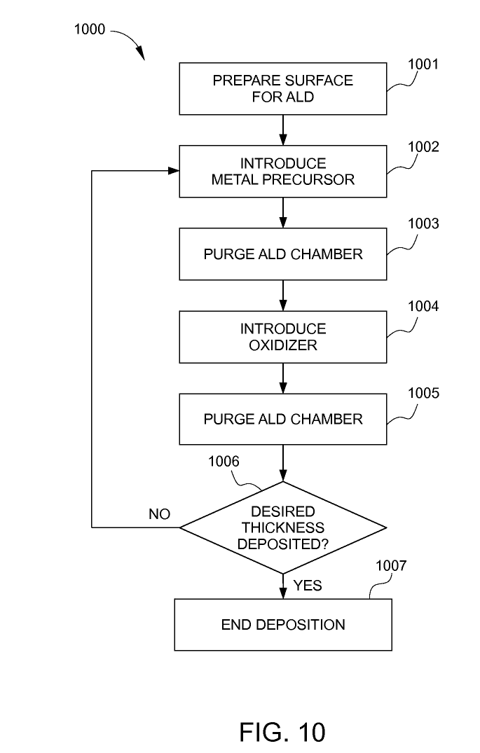

FIG. 10 sets forth a flowchart of method steps in a process sequence 1000 for forming a metal-rich variable resistance layer 206 using a modified ALD process, according to embodiments of the invention. Although the method steps are described in conjunction with memory device 200 in FIG. 4, persons skilled in the art will understand that formation of other resistive switching memory devices using process sequence 1000 is within the scope of the invention.

As illustrated, method 1000 begins at step 1001, in which a metal layer is formed on a suitably prepared and activated surface, such as the surface of electrode 118 after being hydroxylated.

In step 1102, the metal layer is formed by exposure of the prepared and activated surface of electrode 118 to a suitable precursor. For example, for the deposition of a hafnium (Hf) layer, precursors such as tetrakis(dimethylamido)hafnium (Hf(NMe₂)₄), tetrakis(ethylmethylamido)hafnium (Hf(NMeEt)₄), and/or tetrakis(diethylamido)hafnium (Hf(NEt₂)₄) may be used. In another example, for the deposition of a zirconium (Zr) layer, tetrakis(dimethylamido)zirconium (Zr(NMe₂)₄), tetrakis(ethylmethylamido)zirconium (Zr(NMeEt)₄), and/or tetrakis(diethylamido)zirconium (Zr(NEt₂)₄) may be used. In one embodiment, the metal oxide layer in variable resistance layer 206 includes a hafnium layer that is deposited in step 1001 by flowing a hafnium precursor, e.g., tetrakis(dimethylamido)hafnium, tetrakis(ethylmethylamido)hafnium, and/or tetrakis(diethylamido)hafnium at a bubbler temperature of 80° C., rather than at the more typical bubbler temperature of 55° C., thereby making the hafnium oxide more metal-rich or oxygen deficient, thus increasing the oxygen vacancies and defects in the metal oxide film.

In step 1003, the metal precursor used in step 1001 is purged from the ALD chamber, leaving only the adsorbed metal precursor on the substrate surface.

In step 1004, the metal precursor adsorbed in step 1001 undergoes an oxidation process to form a desired metal oxide (MOₓ) layer, such as a hafnium oxide (HfO_{X}) layer. An oxidizer, such as water or ozone (O₃) is introduced into the ALD chamber and reacts with the metal adsorbed metal precursor molecule to create a monolayer of metal oxide, such as hafnium oxide. In some embodiments, with water as oxidizer, a lower bubbler temperature, e.g., 1° C., than a typical bubbler temperature, e.g., 20° C. is used in step 1003 to create an oxygen deficient, i.e., metal rich, metal oxide film. In other embodiments, the duration of the oxidizer pulse is shortened to create a more oxygen-deficient metal oxide film.

In step 1005, the oxidizer used in step 1001 is purged from the ALD chamber, leaving.

In step 1006, the determination is made whether or not the thickness of metal oxide film has reached the desired thickness. If not, method 1000 proceeds to back step 1002. If the thickness of the metal oxide film has reached the desired thickness, method 1000 proceeds to step 1007, in which deposition of the metal oxide film is ended.

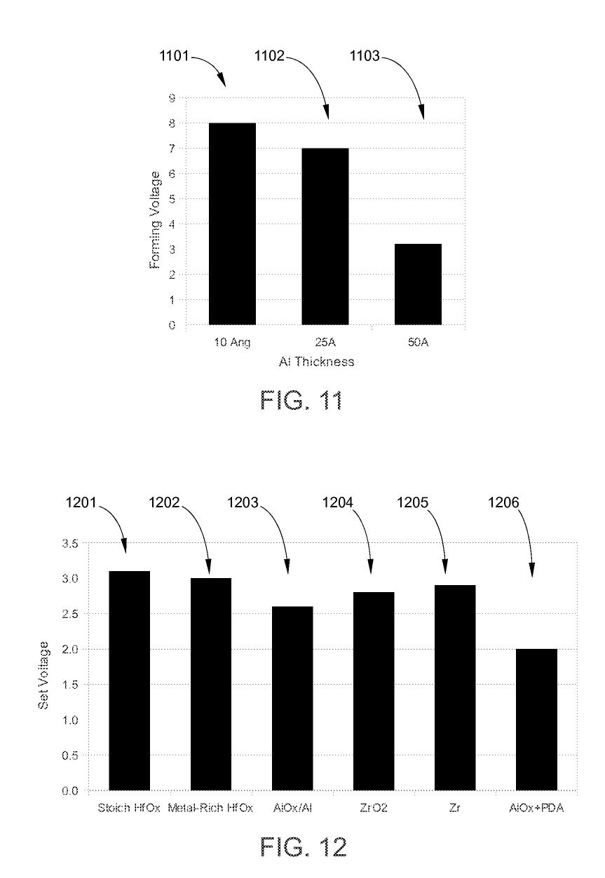

FIG. 11 sets forth forming voltages V_{FORM} measured for three different sets of memory devices that are configured according to embodiments of the invention. Column 1101 presents forming voltages required to initially form a variable resistance layer, such as variable resistance layer 206, in a first set of memory devices substantially similar to memory device 200 in FIG. 4. The memory devices in the first set each include a hafnium oxide host oxide layer substantially similar to metal oxide layer 701 (illustrated in FIG. 7A), a metal-containing defect enhancement layer substantially similar to metal layer 702 (illustrated in FIG. 7B) that consists of a 10 Å aluminum layer, and a TiN electrode 102 and a polysilicon electrode 118. As shown, required forming voltages for the memory devices in the first set vary have a median magnitude of 8 V. Column 1102 presents forming voltages required to initially “electrically” form a variable resistance layer in a second set of memory devices. The memory devices in the second set are identical to the memory devices in the first set, except that the metal-containing defect enhancement layer consists of 25 Å of aluminum. Required forming voltages for the memory devices in the second set have a median magnitude of approximately 7.0 V. Column 1103 presents forming voltages required to initially “electrically” form a variable resistance layer in a third set of memory devices. The memory devices in the third set are identical to the memory devices in the first and second sets, except that the metal-containing defect enhancement layer consists of 50 Å of aluminum. As shown in FIG. 11, required forming voltages for the memory devices in the third set have a median magnitude of approximately 3.2 V.

Inspection of FIG. 11 clearly indicates that the addition of an aluminum defect enhancement layer similar to metal 702 in FIG. 7B reduces forming voltage requirements for resistive memory devices, where a metal-containing defect enhancement layer that is approximately the same thickness as the host oxide layer shows the most benefit.

FIG. 12 sets forth a comparison of minimum set voltages V_{SET} required for various resistive switching memory devices, including prior art memory devices and memory devices configured according to embodiments of the invention. Columns 1201 and 1202 present minimum set voltages V_{SET} required for memory devices configured as prior art resistive switching memory devices. The memory devices associated with columns 1201 and 1202 are similar to memory device 200 in FIG. 4, including a hafnium oxide variable resistance layer that is formed of stoichiometric hafnium oxide for column 1201 and metal-rich hafnium oxide for column 1202. However, as prior art resistive switching devices, the memory devices associated with columns 1201 and 1202 do not include a defect enhancement layer as described herein, such as defect enhancement layer 702 (illustrated in FIG. 7B) or defect enhancement layer 902 (illustrated in FIG. 9B). As shown, the median value of minimum set voltages V_{SET} for such memory devices is −3.1 V to −3.0 V.

Columns 1203-1206 present minimum set voltages V_{SET} required for memory devices configured according to embodiments of the invention. The memory devices for columns 1203-1206 include an electrode 102 formed from TiN, a metal oxide layer 901 that is a hafnium oxide layer, and an electrode 118 that is formed from silicon. Column 1203 shows that the median minimum set voltage V_{SET} is −2.6 V for a memory device with a defect enhancement layer that consists of a second metal layer 902A (illustrated in FIG. 9B) and a second metal oxide layer 902B (illustrated in FIG. 9B), where the second metal layer 902A is a layer of aluminum that is 8 Å thick and the second metal oxide layer 902B is a layer of aluminum oxide (AlO_{X}) that is 30 Å thick. Column 1204 shows that the median minimum set voltage V_{SET} is −2.8 V for a memory device with a defect enhancement layer 902 (illustrated in FIG. 9B) that consists of a layer of zirconium oxide (ZrO_{X}) that is 8 Å thick. Column 1205 shows that the median minimum set voltage V_{SET} is −2.9 V for a memory device with a defect enhancement layer 902 that consists of a layer of zirconium that is 25 Å thick. Column 1206 shows that the median minimum set voltage V_{SET} is −2.0 V for a memory device with a defect enhancement layer 902 that consists of a layer of aluminum oxide (AlO_{X}) that is 20 Å thick and undergoes a post deposition anneal (PDA). Comparison of columns 1201-1202 with columns 1203-1206 indicates that embodiments of the invention significantly reduce the set voltage V_{SET} required for resistive switching memory devices.

While embodiments of the invention are described herein in terms of resistive switching memory elements that are used to form memory arrays, embodiments of the present invention can be applied to other resistive memory devices without deviating from the basic scope of the invention described herein.

In sum, embodiments of the invention provide a nonvolatile resistive memory element with a novel variable resistance layer that includes a metal-rich host oxide having an enhanced defect distribution and methods of forming the same. The novel variable resistance layer operates with reduced switching voltage and current and requires significantly reduced forming voltage when manufactured.

While the foregoing is directed to embodiments of the present invention, other and further embodiments of the invention may be devised without departing from the basic scope thereof, and the scope thereof is determined by the claims that follow.

We claim:

1. A nonvolatile memory element, comprising:
a first layer operable as an electrode layer;
a second layer operable as an electrode layer;
a third layer operable as a variable resistance layer that is disposed between the first layer and the second layer and comprises an oxide of a metal; and
a fourth layer that is disposed adjacent to the third layer and comprises a substantially oxide-free layer of the metal.

2. The nonvolatile memory element of claim 1, wherein the third layer comprises hafnium oxide (HfOₓ) and has a thickness of between about 10 Å and about 100 Å.

3. A nonvolatile memory element, comprising:
a first layer operable as an electrode layer;
a second layer operable as an electrode layer;
a third layer operable as a variable resistance layer that is disposed between the first layer and the second layer and comprises an oxide of a first metal; and
a fourth layer that is disposed adjacent to the third layer and comprises a second metal, wherein a reaction between the oxide of the first metal and the second metal produces an oxide of the second metal, the chemical reaction having a Gibbs free energy of formation that is less than zero.

4. A nonvolatile memory element, comprising:
a first layer operable as an electrode layer;
a second layer operable as an electrode layer;
a third layer operable as a variable resistance layer that is disposed between the first layer and the second layer and comprises an oxide of a first metal; and
a fourth layer that is disposed adjacent to the third layer and comprises a second metal, wherein an oxide of the second metal has a Gibbs free energy of formation that is more negative than a Gibbs free energy of formation of the oxide of the first metal.

5. The nonvolatile memory element of claim 4, wherein the fourth layer comprises a substantially oxide-free layer of the second metal.

6. The nonvolatile memory element of claim 5, wherein the fourth layer further comprises a layer of the oxide of the second metal and wherein the substantially oxide-free layer of the second metal is disposed between the layer of the oxide of the second metal and the third layer.

7. The nonvolatile memory element of claim 4, wherein the fourth layer has a thickness that is no more than a thickness of the third layer.

8. The nonvolatile memory element of claim 4, wherein the fourth layer comprises a layer of the oxide of the second metal.

9. The nonvolatile memory element of claim 4, wherein the third layer comprises hafnium oxide and the second metal comprises a chemical element from the group consisting of aluminum (Al), lanthanum (La), and yttrium (Y).

10. The nonvolatile memory element of claim 4, wherein the third layer comprises zirconium oxide (ZrO_{X}) and the second metal comprises a chemical element from the group consisting of hafnium (Hf), aluminum, lanthanum, and yttrium.

11. A method of forming a nonvolatile memory element, the method comprising:
forming a first layer operable as an electrode layer of the nonvolatile memory element;
forming a second layer above the first layer, wherein the second layer is operable as a variable resistance layer of the nonvolatile memory element and comprises an oxide of a metal;
forming a third layer such that the third layer is ultimately disposed adjacent to the second layer, wherein the third layer comprises a substantially oxide-free layer of the metal;
thermally annealing the third layer; and
forming a fourth layer above the second layer and the third layer, wherein the fourth layer is operable as an electrode layer of the nonvolatile memory element.

12. The nonvolatile memory element of claim 11, wherein the third layer has a thickness that is no more than a thickness of the second layer.

13. The nonvolatile memory element of claim 11, wherein the metal comprises hafnium.

14. A method of forming a nonvolatile memory element, comprising:
forming a first layer operable as an electrode layer of the nonvolatile memory element;
forming a second layer above the first layer, wherein the second layer is operable as a variable resistance layer of the nonvolatile memory element and comprises an oxide of a first metal;
forming a third layer that comprises a second metal such that the third layer is ultimately disposed adjacent to the second layer, wherein an oxide of the second metal has a Gibbs free energy of formation that is more negative than a Gibbs free energy of formation of the oxide of the first metal;
thermally annealing the third layer; and
forming a fourth layer above the second layer and the third layer, wherein the fourth layer is operable as an electrode layer of the nonvolatile memory element.

15. The nonvolatile memory element of claim 14, wherein forming the third layer comprises forming a substantially oxide-free layer of the second metal such that the substantially oxide-free layer of the second metal is ultimately adjacent to the second layer.

16. A method of forming a nonvolatile memory element, the method comprising:
forming a first layer operable as an electrode layer of the nonvolatile memory element;
depositing a metal-rich oxide of a first metal above the first layer using an atomic layer deposition process, wherein the metal rich oxide forms a second layer operable as a variable resistance layer of the nonvolatile memory element; and
forming a third layer above the second layer, wherein the third layer is operable as an electrode layer of the nonvolatile memory element.

17. The method of claim 16, wherein the atomic layer deposition process comprises using a metal precursor having a concentration or partial pressure that is too high for stoichiometric deposition of an oxide of the first metal.

18. The method of claim 16, wherein the atomic layer deposition process comprises a metal precursor step having a duration that is too long for stoichiometric deposition of an oxide of the first metal.

19. The method of claim 16, wherein the atomic layer deposition process comprises flowing a metal precursor at a temperature that is too high for stoichiometric deposition of an oxide of the first metal.

20. The method of claim 16, wherein the atomic layer deposition process comprises using an oxidant that is too dilute for stoichiometric deposition of an oxide of the first metal.
